(19) United States
(12) Patent Application Publication
(10) Pub. No.: US 2026/0052732 A1
(43) Pub. Date: Feb. 19, 2026

(54) POWER GATING BY BACKSIDE WIRING

(71) Applicant: INTERNATIONAL BUSINESS MACHINES CORPORATION, Armonk, NY (US)

(72) Inventors: Yasir Sulehria, Niskayuna, NY (US); Ruilong Xie, Niskayuna, NY (US); Tsung-Sheng Kang, Ballston Lake, NY (US); Sagarika Mukesh, Albany, NY (US); Alexander Reznicek, Troy, NY (US); Nicholas Anthony Lanzillo, Wynantskill, NY (US)

(21) Appl. No.: 18/802,222

(22) Filed: Aug. 13, 2024

(51) Int. Cl. H01L 29/417; H01L 21/283; H01L 21/768; H01L 23/528; H01L 27/088; H01L 29/06; H01L 29/423; H01L 29/66; H01L 29/775; H01L 29/786

(52) U.S. Cl. CPC H10D 30/6729; H01L 21/76877; H01L 23/5286; H01L 21/283; H10D 30/014; H10D 30/43; H10D 30/6735; H10D 30/6757; H10D 62/121; H10D 84/83

(57) ABSTRACT

A semiconductor device includes a field effect transistor having source/drain regions, the source/drain regions having a source/drain region width. Backside contacts are connected to the source/drain regions. The backside contacts have a dimension greater than the source/drain region width. Metal lines are connected to the backside contacts. The metal lines have a gap therebetween and include a metal line width. The metal lines further include metal line extensions that have an extension width that is less than the metal line width and extends beyond the metal line width to increase tip to tip distance between the metal lines while maintaining a pitch across the gap.

### BACKGROUND

The present invention generally relates to semiconductor devices and processing methods, and more particularly to semiconductor structures with backside wiring to enable power gating.

Power gating includes selectively activating or deactivating devices or groups of devices to conserve power on a semiconductor device. Power gates are switchable transistors that are employed to connect local power grids to global power supplies. Local power gating can be done at the cell level, while global power gating can be done at the circuit or block level.

With the reduction in device size, placement of power gates becomes increasingly challenging. Accommodation needs to be made for vias or contacts connecting power lines to devices and vice versa. It remains difficult to reduce spacings between different power supply voltage lines, especially given minimum size requirements for power gate transistors.

Therefore, devices and methods for fabricating devices are needed for backside power gating to permit further scaling in semiconductor devices.

### SUMMARY

In accordance with an embodiment of the present invention, a semiconductor device includes a field effect transistor having source/drain regions, the source/drain regions having a source/drain region width. Backside contacts are connected to the source/drain regions. The backside contacts have a dimension greater than the source/drain region width. Metal lines are connected to the backside contacts. The metal lines have a gap therebetween and include a metal line width. The metal lines further include metal line extensions that have an extension width that is less than the metal line width and extends beyond the metal line width to increase tip to tip distance between the metal lines while maintaining a pitch across the gap.

In other embodiments, the backside contacts can include a tapered profile in a first direction. The backside contacts can include a non-tapered profile in a second direction orthogonal to the first direction. The tapered profile can increase in width with distance from the source/drain regions. The metal lines adjacent to the gap can include a power line having a first voltage on a first side of the gap and a second voltage on a second side of the gap. The first voltage can include a positive supply voltage and the second voltage includes a negative supply voltage. The first voltage can include a local supply voltage and the second voltage includes a global supply voltage. The gap can provide a position for a gating transistor.

In accordance with another embodiment of the present invention, a semiconductor device includes a field effect transistor having source/drain regions, the source/drain regions having a source/drain region width. Shallow trench isolation regions are disposed between the source/drain regions, the shallow trench isolation regions including a tapered profile that increases in width toward the source/drain regions. Backside contacts are connected to the source/drain regions, the backside contacts having a dimension greater than the source/drain region width and disposed between the shallow trench isolation regions. Metal lines are connected to the backside contacts, the metal lines having a gap therebetween and including a metal line width, the metal lines further including metal line extensions that have an extension width that is less than the metal line width and extends beyond the metal line width to increase tip to tip distance between the metal lines while maintaining a pitch across the gap.

In other embodiments, the backside contacts can include a tapered profile in a first direction. The backside contacts can include a non-tapered profile in a second direction orthogonal to the first direction. The tapered profile can increase in width with distance from the source/drain regions. The metal lines adjacent to the gap can include a power line having a first voltage on a first side of the gap and a second voltage on a second side of the gap. The first voltage can include a positive supply voltage and the second voltage includes a negative supply voltage. The first voltage can include a local supply voltage and the second voltage includes a global supply voltage. The gap can provide a position for a gating transistor. The shallow trench isolation regions can include layers having different dielectric materials.

In accordance with another embodiment of the present invention, a semiconductor device includes a field effect transistor having source/drain regions, the source/drain regions having a source/drain region width. Shallow trench isolation regions are disposed between the source/drain regions, the shallow trench isolation regions including a tapered profile that increases in width toward the source/drain regions. Backside contacts are connected to the source/drain regions, the backside contacts having a dimension greater than the source/drain region width and disposed between the shallow trench isolation regions. Metal lines are connected to the backside contacts, the metal lines having a gap therebetween and including a metal line width. The metal lines further include metal line extensions that have an extension width that is less than the metal line width and extends beyond the metal line width to increase tip to tip distance between the metal lines while maintaining a pitch across the gap. A power gating transistor is disposed across the gap.

In other embodiments, the backside contacts can include a tapered profile in a first direction and a non-tapered profile in a second direction orthogonal to the first direction. The tapered profile can increase in width with distance from the source/drain regions. The metal lines adjacent to the gap can include a power line having a first voltage on a first side of the gap and a second voltage on a second side of the gap. The first voltage can include a positive supply voltage, and the second voltage can include a negative supply voltage.

In accordance with another embodiment of the present invention, a semiconductor device includes a field effect transistor having source/drain regions, the source/drain regions having a source/drain region width. Shallow trench isolation regions are disposed between the source/drain regions, the shallow trench isolation regions including a tapered profile that increases in width toward the source/drain regions. Backside contacts are connected to the source/drain regions, the backside contacts having a dimension greater than the source/drain region width and disposed between the shallow trench isolation regions. Metal lines are connected to the backside contacts, the metal lines having a gap therebetween and including a metal line width. The metal lines further include metal line extensions that have an extension width that is less than the metal line width and extends beyond the metal line width to increase tip to tip distance between the metal lines while maintaining a pitch across the gap, wherein the metal lines adjacent to the gap include a power line having a first voltage on a first side of the gap and a second voltage on a second side of the gap, wherein the first voltage includes a local supply voltage and the second voltage includes a global supply voltage. A power gating transistor is disposed across the gap to selectively connect the local supply voltage to the global supply voltage.

In other embodiments, the backside contacts can include a tapered profile in a first direction and a non-tapered profile in a second direction orthogonal to the first direction. The tapered profile can increase in width with distance from the source/drain regions.

In accordance with another embodiment of the present invention, a method for fabricating a semiconductor device includes forming tapered shallow trench isolation regions in a semiconductor substrate; forming sacrificial placeholders in the substrate between the tapered shallow trench isolation regions; growing source/drain regions for transistors on the sacrificial placeholders; removing the substrate; filling voids left by removing the substrate by depositing a sacrificial material between the tapered shallow trench isolation regions and the sacrificial placeholders; depositing a backside interlayer dielectric layer; removing the sacrificial placeholders and sacrificial material to expose the source/drain regions for the transistors and form tapered contact openings; forming backside contacts in the tapered contact openings such that the backside contacts have a width greater than a width of the source/drain regions for the transistors; forming metal lines connected to the backside contacts, the metal lines having a gap therebetween and including a metal line width, the metal lines further including metal line extensions that have an extension width that is less than the metal line width and extends beyond the metal line width to increase tip to tip distance between the metal lines while maintaining a pitch across the gap.

In other embodiments, the backside contacts can include a tapered profile in a first direction and a non-tapered profile in a second direction orthogonal to the first direction. The tapered profile can increase in width with distance from the source/drain regions.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views, taken at section lines X1, X2 and Y as shown in an inset, showing tapered shallow trench isolation regions, sacrificial placeholders, gate structures, source/drain regions, frontside contacts, metal lines, a back end of the line layer and a carrier wafer provided for a semiconductor device, in accordance with an embodiment of the present invention;

FIG. 2 shows cross-sectional views, taken at section lines X1, X2 and Y, showing a substrate removed from a backside of the wafer, in accordance with an embodiment of the present invention;

FIG. 3 shows cross-sectional views, taken at section lines X1, X2 and Y, showing an etch stop layer and a semiconductor layer removed from the backside of the wafer to expose the sacrificial placeholders, in accordance with an embodiment of the present invention;

FIG. 4 shows cross-sectional views, taken at section lines X1, X2 and Y, showing a conformal sacrificial material deposited, in accordance with an embodiment of the present invention;

FIG. 5 shows cross-sectional views, taken at section lines X1, X2 and Y, showing the conformal sacrificial material recessed by an etch, in accordance with an embodiment of the present invention;

FIG. 6 shows cross-sectional views, taken at section lines X1, X2 and Y, showing an interlayer dielectric layer formed on a backside of the wafer, in accordance with an embodiment of the present invention;

FIG. 7 shows cross-sectional views, taken at section lines X1, X2 and Y, showing the sacrificial placeholders and the conformal sacrificial material removed to form tapered contact openings, in accordance with an embodiment of the present invention;

FIG. 8 shows an inset layout view and cross-sectional views, taken at section lines X1, X2 and Y, depicting tapered contacts formed, in accordance with an embodiment of the present invention;

FIG. 9 shows cross-sectional views, taken at section lines X1, X2 and Y, showing the interlayer dielectric layer extended by forming an additionally deposited dielectric on the backside of the wafer, in accordance with an embodiment of the present invention;

FIG. 10 shows an inset layout view and cross-sectional views, taken at section lines X1, X2 and Y, depicting metal lines and metal extensions formed, in accordance with an embodiment of the present invention;

FIG. 11 shows a layout view depicting metal lines and metal extensions formed across a gap having a greater tip to tip distance than a pitch between metal lines, in accordance with an embodiment of the present invention;

FIG. 12 shows a layout view depicting metal lines and metal extensions with backside contacts, in accordance with an embodiment of the present invention; and

FIG. 13 shows cross-sectional views, taken at section lines X1, X2 and Y, showing a backside interconnect layer formed, in accordance with an embodiment of the present invention;

### DETAILED DESCRIPTION

In accordance with embodiments of the present invention, devices and methods are described which include over-sized or enlarged direct backside contacts (DBC) that increase tip to tip (T2T) space across power line gaps while maintaining longitudinal spacing. The increased T2T space enables the placement of power gate transistors of adequate size while maintaining a distance between the power lines.

In an embodiment, a semiconductor device includes a transistor with a first source/drain region connected to a first backside contact, and a second source/drain region connected to a second backside contact. The first source/drain region and second source/drain region are connected to two backside metal lines (e.g., M1 lines) designated with different potentials (voltages). Two backside M1 lines have larger dimensions away from the transistor, and reduced dimensions towards the backside contacts. The first and/or second transistors can include power gating transistors. One of the two backside metal lines can include a local positive power supply voltage line (e.g., VDD) or a local negative power supply voltage line (e.g., VSS), and the other can include a global positive power supply voltage line (e.g., VDD) or a global negative power supply voltage line (e.g., VSS). The backside contact can include a substantially uniform dimension in one dimension and enlarged dimension orthogonal to the one dimension. The enlarged dimension is larger than a width of an active region size (e.g., width of a source/drain region).

In other embodiments, methods for forming a semiconductor structure include forming a tapered shallow trench isolation (STI) and forming transistors with placeholders under source/drain regions between STIs. After a substrate is removed, sacrificial material is formed between the STIs and placeholders. A backside interlayer dielectric is formed. The sacrificial material and the placeholder are exposed and removed. Backside contacts with a bottom dimension larger than a width of the source/drain region are formed. Power rails connecting edges of the backside contacts are formed, such that two power rails with different electrical potentials can connect to two separate backside contacts that are disposed next to each other.

While illustrative embodiments will be described in terms of nanosheet devices, embodiments of the present invention can be applied to other device types including but not limited to fin devices, forksheet devices, etc.

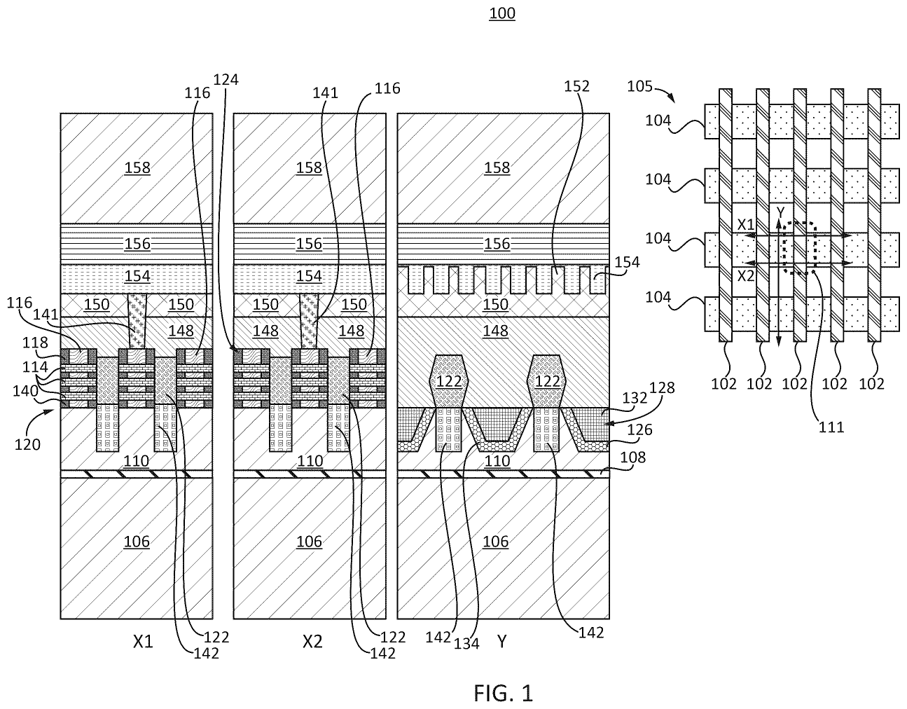

Referring now to the drawings in which like numerals represent the same or similar elements and initially to FIG. 1, devices and methods for manufacturing a nanosheet field effect transistor (FET) device are shown in accordance with embodiments of the present invention.

A wafer 100 includes a substrate 106 on which the FET device will be fabricated. FIG. 1 depicts views X1, X2 and Y taken at corresponding sections X1, X2 and Y in inset 105. Inset 105 shows gate lines 102 and active region lines 104 for reference. Corresponding X1, X2 and Y views are depicted throughout the FIGS. Active region lines 104 represent source/drain (S/D) regions for transistor devices to be formed, and gate lines 102 are represented for such transistor devices. Transistor channels are formed along the active region lines 104 below the gate lines 102. Active region lines 104 can include active regions for N-type field effect transistors (NFETs) and/or P-type field effect transistors (PFETs). In an embodiment, two of the active region lines 104 can be for NFETs, and two for PFETs. An outline of a power gate transistor 111 is illustratively depicted for reference.

The substrate 106 can have a single layer or multiple layers on which the FET device will be fabricated. The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In an embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

Shallow trench isolation (STI) or STI regions 128 are formed in trenches etched in the semiconductor layer 110. The etching process forms a tapered trench 134 for STI regions 128. The tapered trench 134 extends to a width that is larger than a width of the active region line 104 or the source/drain region 122. STI regions 128 can be formed by depositing a dielectric material 126, such as, a nitride, e.g., SiN, followed by a second dielectric material 132, such as, an oxide, e.g., SiNSiO₂, SiOₓN_{y}, SiCO or other suitable compounds. STI regions 128 can be deposited using chemical vapor deposition (CVD), although other deposition methods can be employed. The STI regions 128 can then be etched, e.g., by reactive ion etch (RIE), to a level of the semiconductor layer 110.

A layer stack 120 or stacks are applied to or formed on the semiconductor layer 110. In an embodiment, one or more nanosheets (NS) are applied to the semiconductor layer 110. In another embodiment, the layer stack 120 can be epitaxially grown using different chemistries to form layers having different properties.

In an embodiment, the layer stack 120 of the nanosheet is processed to form channel layers 114 for field effect transistors (FETs) from alternating layers of the nanosheet. The other layers (semiconductor layers) of the nanosheet are removed but are employed for forming inner spacers 140. The inner spacers 140 and spacers 118 include a dielectric material, e.g., a nitride or an oxide. The inner spacers 140 can be formed by laterally etching the nanosheet layer and then filling the recess with a dielectric material. The inner spacers 140 can be formed by filling recesses where nanosheet layers were removed (by etching) with a dielectric material, e.g., SiBCN, SiCN or other suitable dielectric materials. Remaining portions of the nanosheet layer that were recessed for the inner spacers 140 are removed to expose the channel layers 114.

Source/drain regions 122 can be grown using an epitaxial growth process using the channel layer 114 and/or the semiconductor layer 110 (directly or using sacrificial placeholders 142) to initiate crystal growth. Source/drain regions 122 are formed on sacrificial placeholders 142. The semiconductor layer 110 is recessed to form trenches, e.g., by reactive ion etching (RIE). Within the trenches recessed into the semiconductor layer 110, the sacrificial placeholder 142 is formed. The sacrificial placeholder 142 can be epitaxially grown in the trenches of semiconductor layer 110. The sacrificial placeholder 142 can include SiGe or other epitaxial grown material that can be selectively removed relative to the semiconductor layer 110.

The source/drain regions 122 can include Si or SiGe. In an embodiment, the source/drain regions 122 can be designated as P-type or N-type devices. For example, if the source/drain regions 122 include N-type devices then the source/drain regions 122 can include Si. In another example, if the source/drain regions 122 include P-type devices then the source/drain regions 122 can include SiGe. The source/drain regions 122 can be appropriately doped during their formation. For example, the source/drain regions 122 can be doped by introducing p dopants (e.g., B, Ga, etc.) during epitaxial formation. Similarly, the source/drain regions 122 can be doped by introducing n dopants (e.g., P, As, etc.) during epitaxial formation.

In some embodiments, a dummy gate material is first employed in gate structures 124.

The dummy gates are removed and a gate dielectric layer (not shown) is deposited to cover the channel layers 114. The gate dielectric layer can be formed by, e.g., chemical wet processes, chemical vapor deposition (CVD) and/or atomic layer deposition (ALD). Suitable examples of the gate dielectric layer can include a silicon oxide interface layer followed by a high-K dielectric oxide that can include, but is not limited to: A1₂O₃, ZrO₂, HfO₂, Ta₂O₃, TiO₂ and combinations thereof.

A gate electrode 116 is formed over the gate dielectric layer and fills spaces between the channel layers 114 that the dummy gates once occupied. This process is known as a replacement metal gate (RMG) process to form High-K Metal Gate (HKMG) structures for selectively activating FETs. The gate electrode 116 can include at least one gate conductor. The gate conductor can include any conductive metal including, but not limited to W, Ni, Ti, Mo, Ta, Cu, Pt, Ag, Au, Ru, Ir, Rh, and Re, and alloys that include at least one of these conductive materials. The gate conductor can include one or more layers of conductive materials. In one example, a second conductive material may be formed. When a combination of conductive elements is employed, an optional diffusion barrier material such as TaN or WN may be formed between the conductive materials. The gate conductor can be deposited by CVD, plasma enhanced CVD (PECVD), atomic layer deposition (ALD) or other suitable deposition process.

An interlayer dielectric (ILD) 148 is deposited over the wafer 100. The ILD 148 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The ILD 148 can be deposited using CVD, although other deposition methods can be employed. The ILD 148 is planarized, e.g., by chemical mechanical polishing (CMP).

A back end of the line (BEOL) ILD 150 is deposited over the wafer 100. The BEOL ILD 150 can include any suitable material, e.g., silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The BEOL ILD 150 can be deposited using CVD, although other deposition methods can be employed. The BEOL ILD 150 is planarized, e.g., by CMP.

Middle of the line contacts, frontside contacts and or vias 141 are formed by a conductive fill to make connections with the gate electrode 116 (and/or the source/drain regions 122) from a top or frontside of the wafer 100. Prior to the conductive fill, a silicide liner (not shown), such as Ti, Ni, NiPt can be deposited first, then a diffusion barrier (not shown) can be formed. The diffusion barrier can include, e.g., TiN, TaN, or similar materials. The silicide liner and the diffusion barrier can be deposited in the trench or hole (e.g., by ALD). The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the contacts or vias 141.

Another dielectric layer 152 is deposited and patterned to form trenches in which metal lines 154 are formed. The dielectric layer 152 can include a same or similar material as that of BEOL ILD 150. A diffusion barrier can be employed and include, e.g., TiN, TaN, or similar materials. The metal lines 154 can include materials, such as, e.g., Cu, Ru, Mo, Rh, W, Ir, and alloys or combinations of these and other conductive materials. In a particularly useful embodiment, the metal lines 154 include Cu. The metal lines 154 can be formed using a deposition method, such as, e.g., CVD, PECVD, ALD or any other suitable deposition method. The metal lines 154 can be planarized, e.g., by CMP.

Metallization structures for a frontside back end of the line (BEOL) layer 156 are formed to connect to gates and source/drain regions of the field effect transistors. The BEOL layer 156 can include additional levels of vias and metal lines as needed to complete the frontside of the wafer 100.

A carrier wafer 158 can be bonded to the wafer 100 on the BEOL layer 156. The carrier wafer provides support and transportability to the wafer 100 for further processing which includes flipping the wafer 100 and removing portions of a bottom side.

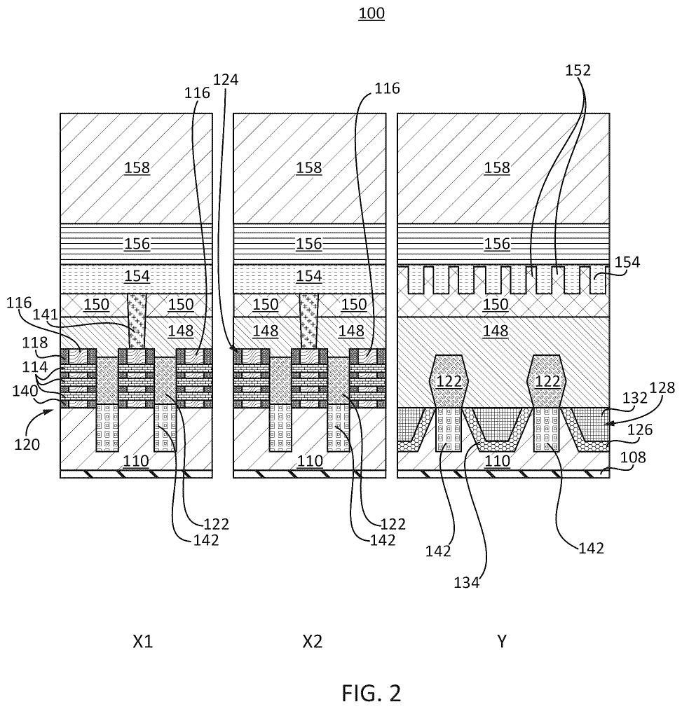

Referring to FIG. 2, the wafer 100 can be flipped to process features on the bottom side.

However, for clarity and consistency, the wafer 100 will be shown in the FIGS. in a same orientation as previously described with continued and consistent reference to bottom/top. The substrate 106 is removed from the bottom side of the wafer 100. The substrate 106 is removed from the bottom side of the wafer 100. The substrate 106 can be removed by an etch process that stops on the etch stop layer 108.

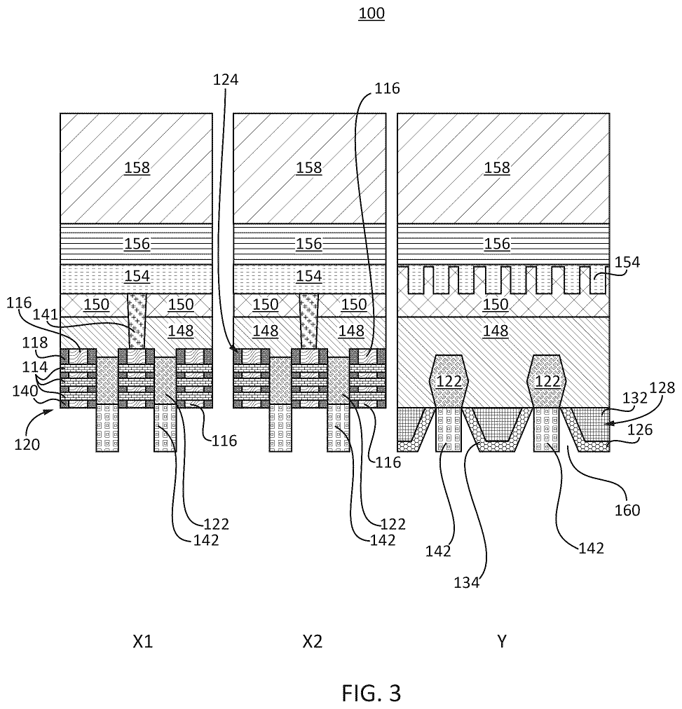

Referring to FIG. 3, the etch stop layer 108 is then removed by an etch process. In an alternate embodiment, a CMP process can be employed. With the removal of the etch stop layer 108, the semiconductor layer 110 is exposed. The semiconductor layer 110 is removed by an etch process that selectively removes the material of the semiconductor layer 110. The etch of the semiconductor layer 110 is performed selective to the sacrificial placeholders 142 and the dielectric material 126 of the STI regions 128. The removal of the semiconductor layer 110 leaves a void 160 in regions around the sacrificial placeholders 142. In section Y, the void 160 follows the tapered contours of the STI regions 128.

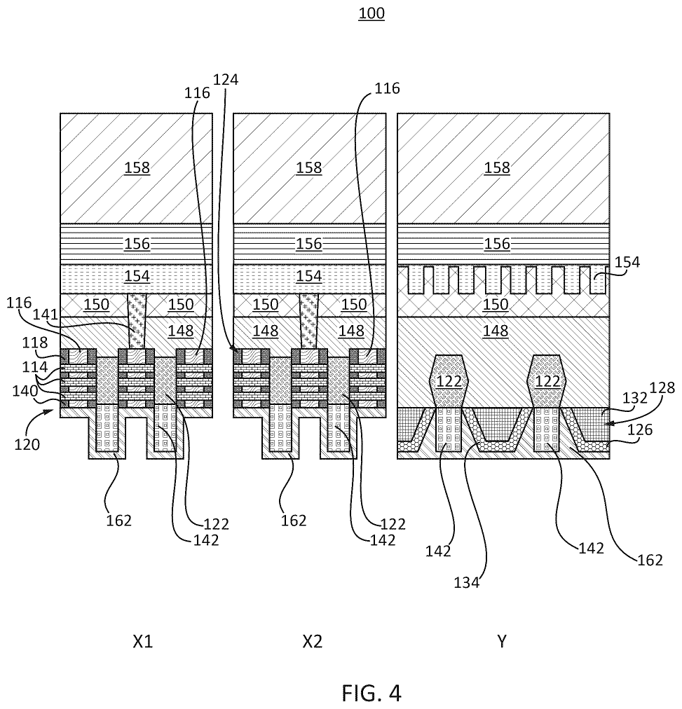

Referring to FIG. 4, a conformal sacrificial dielectric layer 162 is deposited to fill the void 160 (FIG. 3). A deposition method, such as, e.g., CVD, PECVD, ALD can be employed to deposit the conformal sacrificial dielectric layer 162. The conformal sacrificial dielectric layer 162 can include, e.g., TiOx, although other dielectric material scan be employed.

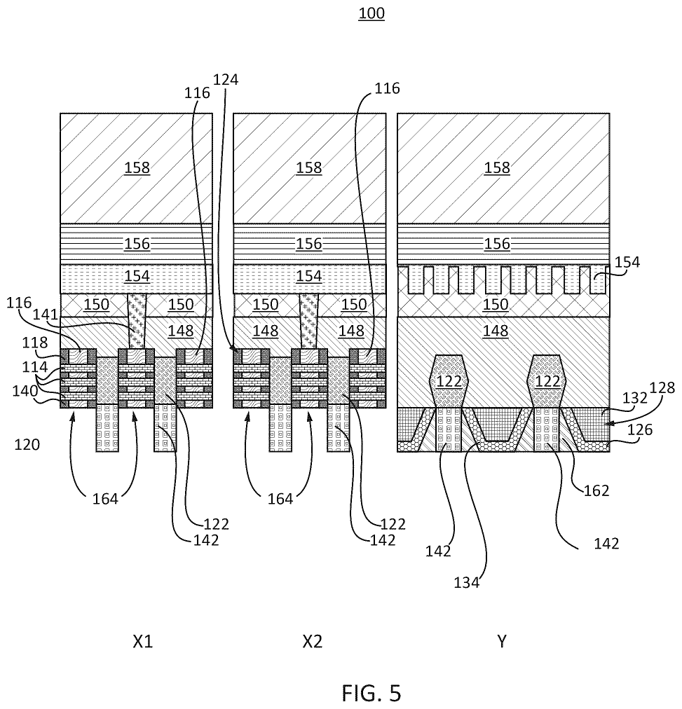

Referring to FIG. 5, an isotropic etch process is performed such as, e.g., a wet etch, to remove portions of the conformal sacrificial dielectric layer 162. The portions of the conformal sacrificial dielectric layer 162 that are removed include portions in contact with the sacrificial placeholders 142 and portions in contact with surfaces 164 between the sacrificial placeholders 142. The isotropic etch process selectively removes the conformal sacrificial dielectric layer 162 with respect to the surface 164, the sacrificial placeholders 142 and the dielectric material 126.

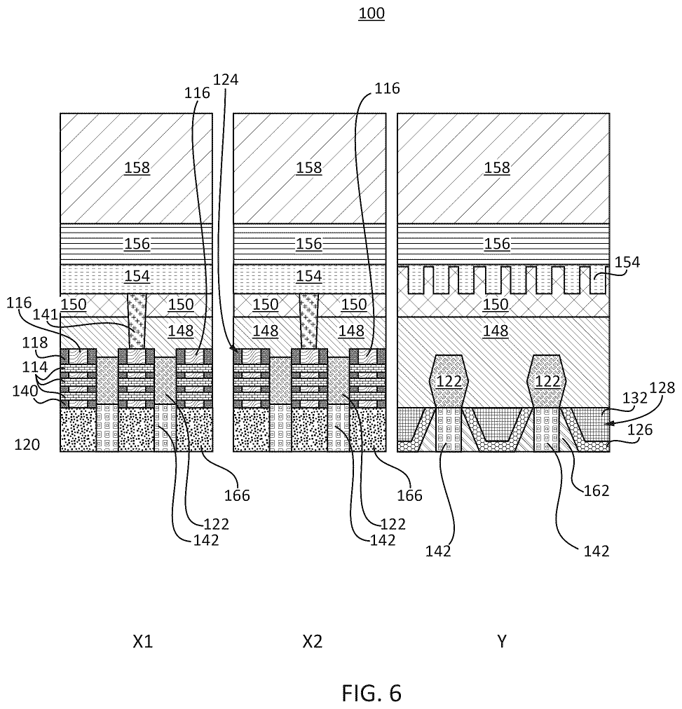

Referring to FIG. 6, an interlayer dielectric (ILD) 166 is formed to replace the substrate 106 that was removed. The ILD 166 can be formed in accordance with the same of different processes and ILD 148 or BEOL ILD 150 and can include a same or different material. The ILD 166 can be planarized, e.g., by CMP to expose the sacrificial placeholders 142.

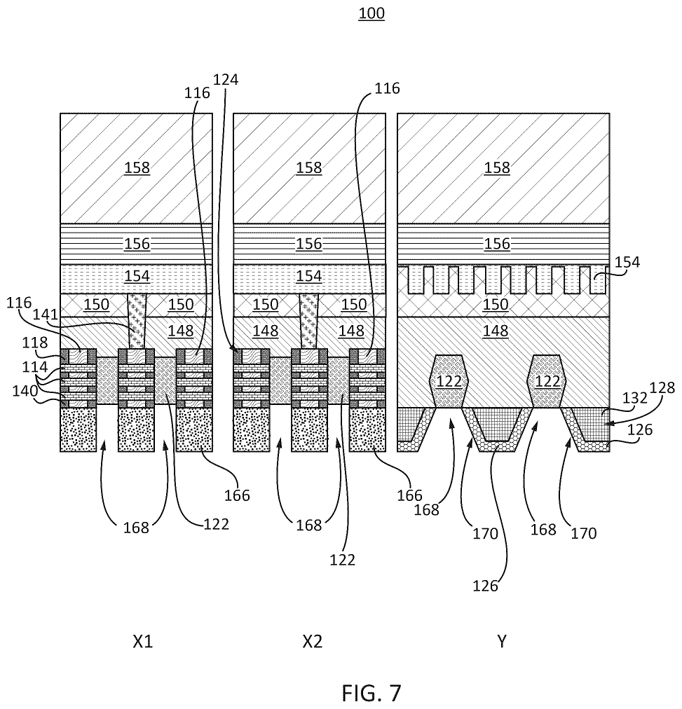

Referring to FIG. 7, some or all of the sacrificial placeholders 142 exposed from the bottom side are removed by etching. The sacrificial placeholders 142 designated for contact formation are not masked so that the sacrificial placeholders 142 are removed to expose the source/drain regions 122. A same or different etch process can be employed to remove the remaining portions of the conformal sacrificial dielectric layer 162. The etch process can include a dry etch or wet etch that selectively removes the sacrificial placeholders 142 to form contact openings 168. The contact openings 168 include a width dimension in the Y section that is wider than the source/drain regions 122 to which the contact openings 168 are adjacent. The contact opening in the Y section includes a tapered profile 170 that fans out from the source/drain regions 122, getting wider to a point where it exceeds the width of the source/drain regions 122.

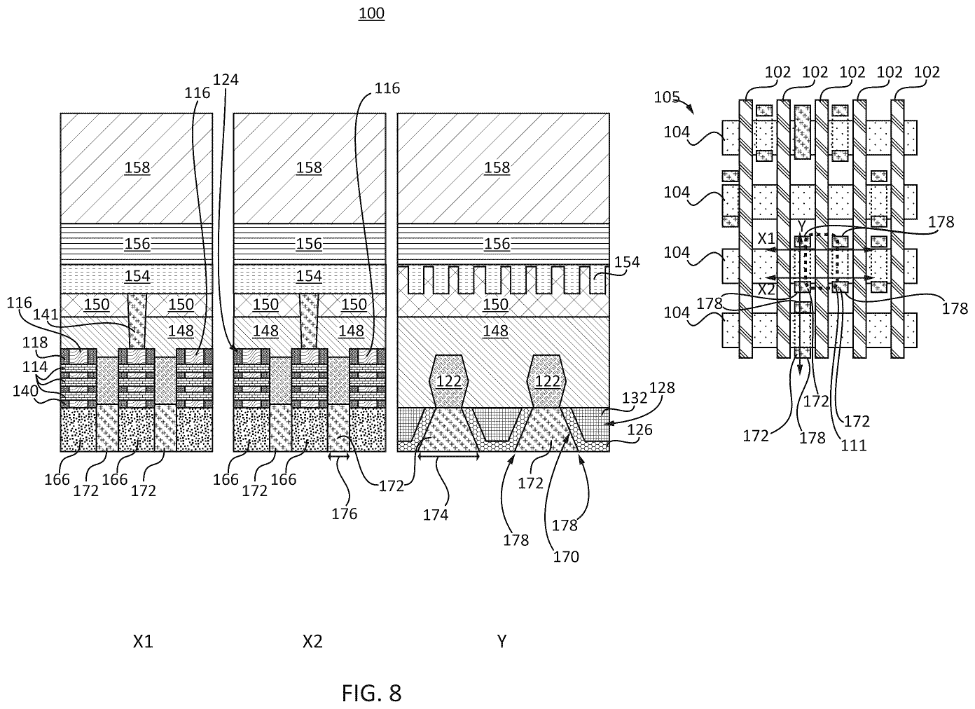

Referring to FIG. 8, contact formation can begin by forming a silicide liner (not shown), such as Ti, Ni, NiPt, which is deposited first, then a diffusion barrier (not shown) can be formed in the openings left by removing the sacrificial placeholders 142 prior to a conductive fill. The diffusion barrier can include, e.g., TiN, TaN, or similar materials. A conductive fill is performed to fill the openings. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form backside contacts 172.

The backside contacts 172 take on the profile of the contact openings 168 (FIG. 7). The backside contacts 172 include a dimension 174 in the Y section that is wider than the source/drain regions 122 in the Y cross-section. The backside contacts 172 include a dimension 176 in the X and X2 sections that are narrower than the dimension 174 in the Y cross-section. This is further illustrated in the inset 105. The backside contacts in the Y section include the tapered profile 170 that fans out from the source/drain regions 122, getting wider to a point where it exceeds a width of the source/drain regions 122 at extended portions 178.

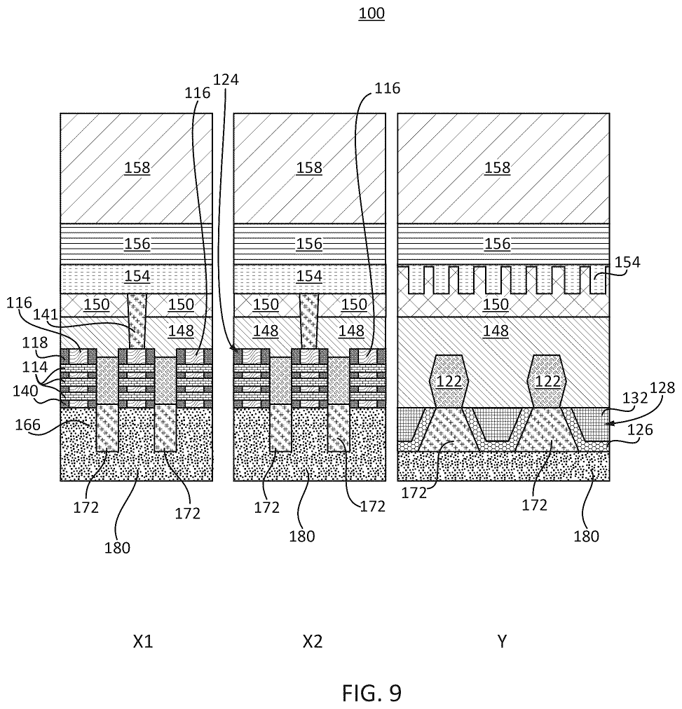

Referring to FIG. 9, an additional deposition 180 extends the ILD 166. The additional deposition 180 can include the same materials or different materials than the ILD 166. The additional deposition 180 can be planarized, e.g., by CMP.

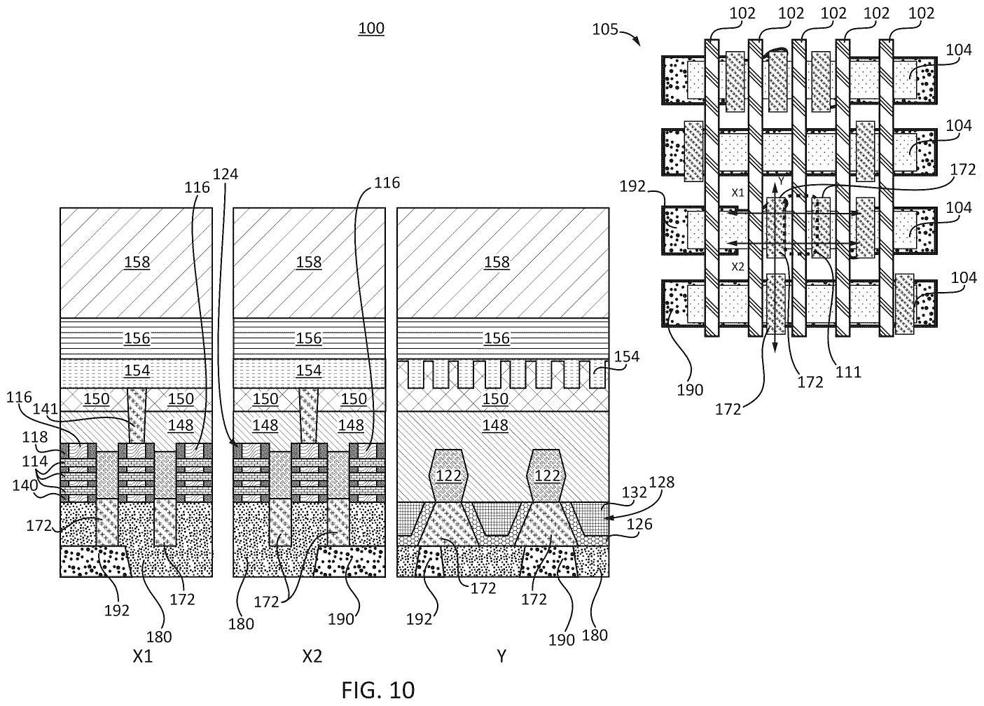

Referring to FIG. 10, the additional deposition 180 is patterned and etched to form trenches for metal lines (power lines) to be formed. A diffusion barrier (not shown) can be formed in the trenches formed in the additional deposition 180 prior to a conductive fill. The diffusion barrier can include, e.g., TiN, TaN, or similar materials. A conductive fill is performed to fill the trenches. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form metal lines 190 and 192.

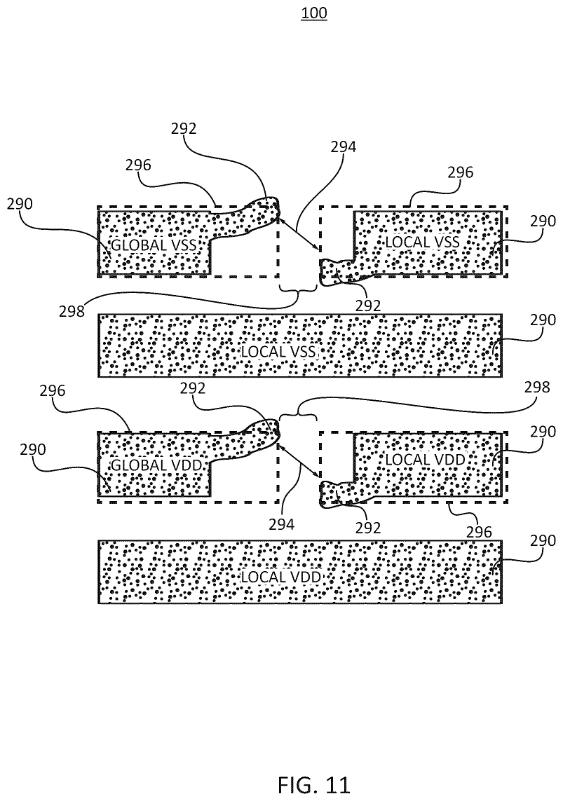

The patterning of the additional deposition 180 can include patterning special features that include recesses and/or extensions in the metal lines 190 (and/or metal line 192) that will accommodate the wider dimensions of the contacts 172. For example, in section Y, metal line 192 connects to the contact 172 over a smaller portion of the contact surface than the metal line 190 connects to its corresponding contact 172. The special features can include dimensions smaller than a width of the metal line 190 in section Y. The special features will be described in greater detail with reference to FIG. 11.

In an embodiment, the metal lines 190 and 192 can include power lines. In an example, metal line 192 can include a global positive supply voltage (VDD) line and metal line 190 can include a local positive supply voltage (VDD) line (or vice versa). In another example, metal line 192 can include a global negative supply voltage (VSS) line and metal line 190 can include a local negative supply voltage (VSS) line (or vice versa). Other configurations can include VDD and VSS lines adjacent to one another and can include global or local lines (or other potentials).

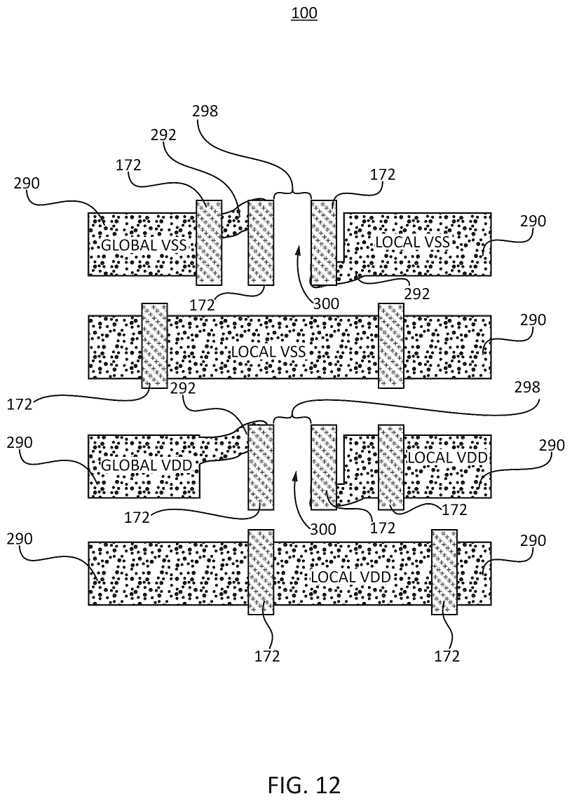

Referring to FIG. 11, a layout view shows full-dimension (metal line width) metal lines 290 with metal line extensions 292. The metal lines 190 shown in cross-section Y in FIG. 10 correspond with the metal lines 290 having a full width dimension. The metal lines 192 shown in cross-section Y in FIG. 10 correspond with the metal line extensions 292. The metal line extensions 292 are special features that extend beyond sides of the metal lines 290. The metal line extensions 292 meet the extended dimensions of the contacts 172 (shown in FIG. 12) to make a connection that increases a tip to tip (T2T) spacing 294 between two adjacent longitudinally placed lines (metal lines 290) but maintains a pitch distance 298 between the metal line extensions 292. Metal line footprints 296 are provided as dashed boxes to show metal line dimensions without metal line extensions 292. The metal line extensions 292 extend laterally beyond the width of the metal line footprint 296 to develop the T2T spacing 294 which provides a diagonal distance that exceeds the pitch distance 298. This permits metal lines of different potential (e.g., global versus local or VDD versus VSS) to be arranged adjacent to one another without interfering with device sizes for transistors, such as power gate transistors that can maintain their size (pitch) despite a reduced scale of the semiconductor device.

FIG. 11 illustratively depicts global VSS and local VSS across the T2T spacing 294 and global VDD and local VDD across the T2T spacing 294. However, it should be understood that other configurations are contemplated, e.g., VDD and VSS or other potentials can be separated by the T2T spacing 294, etc.

Referring to FIG. 12, the contacts 172 are shown disposed on the metal lines 290 and the metal line extensions 292. The contacts 172 extend beyond the sides of the metal lines 290 and connect to the metal line extensions 292. The metal line extensions 282 connect to the contacts 172 laterally beyond the sides of the metal lines 290 and between the metal lines 290. While the pitch distance 298 is maintained, an appropriately sized space 300 is provided for gating transistors 111 (FIG. 10) (or other types of transistors). The gating transistors 111 longitudinally connect the metal lines 290 across the space 300 to activate or deactivate a cell (local) or a block (global). In the example of FIG. 12, a global VSS (VDD) line and be selectively connected to a local VSS (VDD) line.

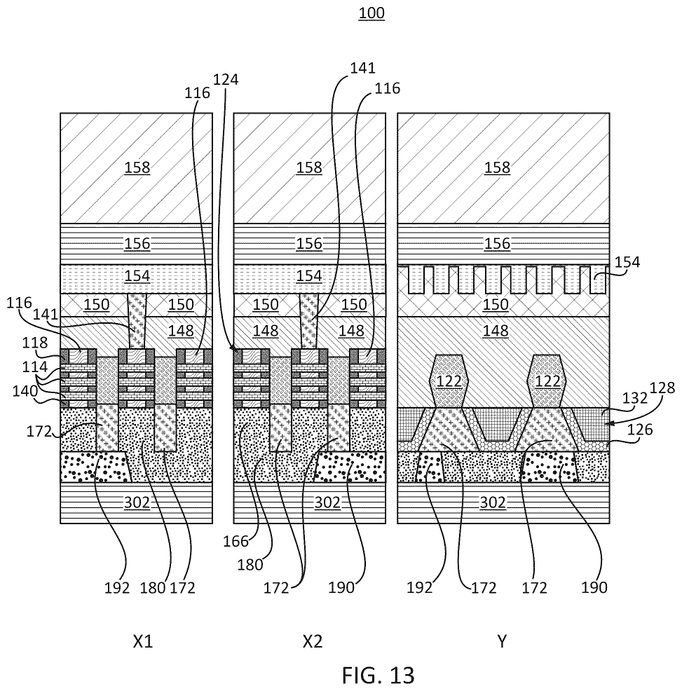

Referring to FIG. 13, a backside interconnect layer 302 can include metal structures and dielectric layers to complete the bottom side of a FET device and provide electrical access and power to devices formed therein. The backside interconnect layer 302 is formed on the additional deposition 180 of the ILD 166 and can include the backside contacts 172 and metal lines 190, 192. The backside interconnect layer 302 can include active devices, such as power gating transistors and metal structures to connect to control circuits.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor-or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a field effect transistor having source/drain regions, the source/drain regions having a source/drain region width;
backside contacts connected to the source/drain regions, the backside contacts having a dimension greater than the source/drain region width; and
metal lines connected to the backside contacts, the metal lines having a gap therebetween and including a metal line width, the metal lines further including metal line extensions that have an extension width that is less than the metal line width and extends beyond the metal line width to increase tip to tip distance between the metal lines while maintaining a pitch across the gap.

2. The semiconductor device as recited in claim 1, wherein the backside contacts include a tapered profile in a first direction.

3. The semiconductor device as recited in claim 2, wherein the backside contacts include a non-tapered profile in a second direction orthogonal to the first direction.

4. The semiconductor device as recited in claim 2, wherein the tapered profile increases in width with distance from the source/drain regions.

5. The semiconductor device as recited in claim 1, wherein the metal lines adjacent to the gap include a power line having a first voltage on a first side of the gap and a second voltage on a second side of the gap.

6. The semiconductor device as recited in claim 5, wherein the first voltage includes a positive supply voltage and the second voltage includes a negative supply voltage.

7. The semiconductor device as recited in claim 5, wherein the first voltage includes a local supply voltage and the second voltage includes a global supply voltage.

8. The semiconductor device as recited in claim 1, wherein the gap provides a position for a gating transistor.

9. A semiconductor device, comprising:
a field effect transistor having source/drain regions, the source/drain regions having a source/drain region width;
shallow trench isolation regions disposed between the source/drain regions, the shallow trench isolation regions including a tapered profile that increases in width toward the source/drain regions;
backside contacts connected to the source/drain regions, the backside contacts having a dimension greater than the source/drain region width and disposed between the shallow trench isolation regions; and
metal lines connected to the backside contacts, the metal lines having a gap therebetween and including a metal line width, the metal lines further including metal line extensions that have an extension width that is less than the metal line width and extends beyond the metal line width to increase tip to tip distance between the metal lines while maintaining a pitch across the gap.

10. The semiconductor device as recited in claim 9, wherein the backside contacts include a tapered profile in a first direction.

11. The semiconductor device as recited in claim 10, wherein the backside contacts include a non-tapered profile in a second direction orthogonal to the first direction.

12. The semiconductor device as recited in claim 10, wherein the tapered profile increases in width with distance from the source/drain regions.

13. The semiconductor device as recited in claim 9, wherein the metal lines adjacent to the gap include a power line having a first voltage on a first side of the gap and a second voltage on a second side of the gap.

14. The semiconductor device as recited in claim 13, wherein the first voltage includes a positive supply voltage and the second voltage includes a negative supply voltage.

15. The semiconductor device as recited in claim 13, wherein the first voltage includes a local supply voltage and the second voltage includes a global supply voltage.

16. The semiconductor device as recited in claim 9, wherein the gap provides a position for a gating transistor.

17. The semiconductor device as recited in claim 9, wherein the shallow trench isolation regions include layers having different dielectric materials.

18. A semiconductor device, comprising:
a field effect transistor having source/drain regions, the source/drain regions having a source/drain region width;
shallow trench isolation regions disposed between the source/drain regions, the shallow trench isolation regions including a tapered profile that increases in width toward the source/drain regions;
backside contacts connected to the source/drain regions, the backside contacts having a dimension greater than the source/drain region width and disposed between the shallow trench isolation regions;
metal lines connected to the backside contacts, the metal lines having a gap therebetween and including a metal line width, the metal lines further including metal line extensions that have an extension width that is less than the metal line width and extends beyond the metal line width to increase tip to tip distance between the metal lines while maintaining a pitch across the gap; and
a power gating transistor disposed across the gap.

19. The semiconductor device as recited in claim 18, wherein the backside contacts include a tapered profile in a first direction and a non-tapered profile in a second direction orthogonal to the first direction and the tapered profile increases in width with distance from the source/drain regions.

20. The semiconductor device as recited in claim 18, wherein the metal lines adjacent to the gap include a power line having a first voltage on a first side of the gap and a second voltage on a second side of the gap.

21. The semiconductor device as recited in claim 20, wherein the first voltage includes a positive supply voltage and the second voltage includes a negative supply voltage.

22. A semiconductor device, comprising:
a field effect transistor having source/drain regions, the source/drain regions having a source/drain region width;
shallow trench isolation regions disposed between the source/drain regions, the shallow trench isolation regions including a tapered profile that increases in width toward the source/drain regions;
backside contacts connected to the source/drain regions, the backside contacts having a dimension greater than the source/drain region width and disposed between the shallow trench isolation regions;
metal lines connected to the backside contacts, the metal lines having a gap therebetween and including a metal line width, the metal lines further including metal line extensions that have an extension width that is less than the metal line width and extends beyond the metal line width to increase tip to tip distance between the metal lines while maintaining a pitch across the gap, wherein the metal lines adjacent to the gap include a power line having a first voltage on a first side of the gap and a second voltage on a second side of the gap, wherein the first voltage includes a local supply voltage and the second voltage includes a global supply voltage; and
a power gating transistor disposed across the gap to selectively connect the local supply voltage to the global supply voltage.

23. The semiconductor device as recited in claim 22, wherein the backside contacts include a tapered profile in a first direction and a non-tapered profile in a second direction orthogonal to the first direction and the tapered profile increases in width with distance from the source/drain regions.

24. A method for fabricating a semiconductor device, comprising:
forming tapered shallow trench isolation regions in a substrate;
forming sacrificial placeholders in the substrate between the tapered shallow trench isolation regions;
growing source/drain regions for transistors on the sacrificial placeholders;
removing the substrate;
filling voids left by removing the substrate by depositing a sacrificial material between the tapered shallow trench isolation regions and the sacrificial placeholders;
depositing a backside interlayer dielectric layer;
removing the sacrificial placeholders and sacrificial material to expose the source/drain regions for the transistors and form tapered contact openings;
forming backside contacts in the tapered contact openings such that the backside contacts have a width greater than a width of the source/drain regions for the transistors; and
forming metal lines connected to the backside contacts, the metal lines having a gap therebetween and including a metal line width, the metal lines further including metal line extensions that have an extension width that is less than the metal line width and extends beyond the metal line width to increase tip to tip distance between the metal lines while maintaining a pitch across the gap.

25. The method as recited in claim 24, wherein the backside contacts include a tapered profile in a first direction and a non-tapered profile in a second direction orthogonal to the first direction and the tapered profile increases in width with distance from the source/drain regions.
